(19) United States
(12) Patent Application Publication
(10) Pub. No.: US 2026/0099656 A1
(43) Pub. Date: Apr. 9, 2026

(54) PIKAN-BASED SEEPAGE SIMULATION METHOD FOR HETEROGENEOUS RESERVOIRS

(71) Applicants: Yangtze University, Jingzhou (CN); Western Research Institute of Yangtze University, Karamay (CN)

(72) Inventors: Yuhui Zhou, Jingzhou (CN); Xiang Rao, Jingzhou (CN); Hui Zhao, Jingzhou (CN); Guanglong Sheng, Jingzhou (CN); Ruiqi Zong, Jingzhou (CN); Fankun Meng, Jingzhou (CN); Zongfa Li, Jingzhou (CN); Shaoyang Geng, Jingzhou (CN); Yunfeng Xu, Jingzhou (CN); Wei Liu, Jingzhou (CN); Wentao Zhan, Jingzhou (CN); Liang Yan, Jingzhou (CN); Penghua Luo, Jingzhou (CN); Yuchen Pei, Jingzhou (CN)

(73) Assignees: Yangtze University, Jingzhou, HB (CN); Western Research Institute of Yangtze University, Karamay, XJ (CN)

(21) Appl. No.: 19/322,667

(22) Filed: Sep. 8, 2025

(30) Foreign Application Priority Data
Oct. 21, 2024 (CN) 202411468479.1

(51) Int. Cl. G06F 30/28; G06F 30/27

(52) U.S. Cl. CPC G06F 30/28; G06F 30/27

(57) ABSTRACT

The present disclosure provides a PIKAN-based heterogeneous reservoir seepage simulation method, which belongs to the field of heterogeneous reservoir development technology, including the following steps: S1, using three independent KAN networks to approximate the PIKAN of pressure p, velocity component vₓ and velocity component v_{y} respectively; S2, constructing a loss function of the mixed pressure-velocity formula including the residual of the mass conservation formula, the residual of Darcy's law and the residual of the relevant boundary conditions, and optimizing the loss function. The present disclosure adopts the above-mentioned PIKAN-based heterogeneous reservoir seepage simulation method, introduces KAN into the flow simulation of porous media for the first time, and provides a preliminary reference for the development of general seepage simulation tools based on PIKAN.

### TECHNICAL FIELD

The present disclosure relates to the field of heterogeneous reservoir development technology, in particular to a PIKAN-based heterogeneous reservoir seepage simulation method.

Additionally disclosed are methods of extracting water, oil or gas resources from heterogeneous reservoirs comprising using the constructing a PIKAN reservoir seepage models and implementing water, oil or gas extraction based on predicted seepage patterns.

### BACKGROUND

Multilayer Perceptron (MLP) is a deep learning model based on a Feedforward Neural Network. MLP's multi-layer nested internal structure and interaction between weights and nodes enhance its ability to express and adapt to complex tasks; however, this also makes the model less interpretable and may lead to over-adaptation to the noise and details of the training data, resulting in overfitting problems.

PINN (Physics-Informed Neural Network) based on MLP is a semi-supervised learning or unsupervised learning neural network method. It may not only learn from the labeled training data samples, like traditional neural networks, but also obtain an approximate solution to differential equations directly, according to the information of the differential equation's definite problem, in the case of unlabeled data. PINN has been proven to be effective and interpretable in solving complex practical problems with noisy data and involving physical laws, making it widely used in various scientific and engineering fields.

At present, PINN has also been widely used in flow simulation in porous media. In the current study, fluid pressure is used as a state variable to simulate the flow in porous media by substituting Darcy's law into the continuity formula. The continuity formula, boundary conditions, and initial conditions are embedded in the loss function as physical constraints to ensure that the neural network learns the solution that conforms to the seepage law. The gradient of the loss function with respect to the neural network parameters depends on the spatial derivative of the medium permeability calculated by the automatic differentiation technique. However, porous media are usually heterogeneous. When the permeability is discontinuous in space, the use of automatic differentiation technology will lead to the non-physical and non-conservation of the solution. To solve this problem, Tartakovsky et al. in 2020, He and Tartakovsky in 2021 used analytical permeability expressions to represent heterogeneity, but it may be very difficult to obtain such analytical expressions in practical applications. Zhang et al. in 2023 and Yan et al. in 2024 used the finite volume method to discretize the seepage formula in the heterogeneous computational domain, so as to replace the original continuous partial differential equation with the discrete finite volume format as the physical part of the error function. However, this implementation method may cause PINNs to lose the advantage of directly using differential formulas to obtain approximate solutions, and its accuracy will also be limited by the error of the numerical discrete format itself, which reduces the necessity of its application, because in the case of existing numerical discrete formats. Direct calculation of numerical solutions is generally much more convenient than iterative training of neural networks, which require a large amount of computing resources. In addition, the domain decomposition technique may also be used to divide the entire heterogeneous computing domain, so that each subdomain may be processed separately. However, this also depends on the actual heterogeneous distribution, which is still difficult to apply directly in the case of strong heterogeneity, or the robustness of the method is poor. In 2023, Lehmann et al. proposed to use the mixed pressure-velocity formula to replace the pure pressure model with only pressure as the main unknown for PINN modeling of heterogeneous porous media flow, and found that the mixed formula may achieve higher calculation accuracy and better convergence. This method may directly avoid the derivation of discontinuous heterogeneous functions and is a robust method for dealing with strong heterogeneous reservoir properties.

The successful application of PINN is due to its MLP as the main neural network structure to approximate the complex nonlinear mapping relationship. The universal approximation theorem shows that when the MLP has enough neurons and layers, it may approximate any continuous function to any precision. Although MLP is widely used as the cornerstone of today's deep learning models, it also has significant shortcomings. In 1987, Hecht-Nielsen proposed an alternative to the MLP-Kolmogorov network, which is based on the Kolmogorov-Arnold representation theorem. This theorem asserts that any sufficiently smooth multivariate function may be expressed as a superposition of univariate functions. However, the properties of univariate functions in the original Kolmogorov-Arnold representation theorem are usually very poor, which makes the Kolmogorov network with shallow structure almost ineffective in practical applications.

Recently, Liu et al. proposed KAN (Kolmogrov-Arnold network) in 2024, which deepens the shallow Kolmogorov network to construct univariate functions with good properties. The core feature of KAN is that it has a learnable activation function on the edges (i.e., weights) of the network, rather than using a fixed activation function on the nodes (i.e., neurons) like traditional MLPs. Therefore, KANs do not have a linear weight matrix. On the contrary, each weight parameter is replaced by a learnable one-dimensional function, parameterized as a spline function, and the nodes of KANs simply sum the incoming signals without applying any nonlinearity. Compared with MLPs, KAN achieves higher accuracy with fewer parameters in various tasks, brings greater performance improvement with the increase of model size, and may provide interpretability and interactivity that MLPs do not have. Although the weight parameters of each MLP are transformed into spline functions of KAN, KAN usually allows smaller computational graphs than MLP, and thus does not introduce additional computational costs. In the original KAN, the B-spline is used to construct the activation function because of its excellent fitting ability. Numerical analysis includes a variety of orthogonal polynomials (Hermite polynomials, Legendre polynomials, and Chebyshev polynomials), including other traditional approximation functions (such as radial basis functions), which may replace the B-spline function in the original KAN. Therefore, the essential core of KAN is a composite function framework composed of learnable activation functions.

KAN is also currently used to solve differential equations and operator learning. In 2024, Wang et al. systematically compared the calculation performance of KAN-based PIKNN and MLP-based PINNs in different forms of PDEs, proving the superiority of PIKAN in dealing with many mechanical problems.

However, PIKAN has not been fully applied to the field of porous media seepage. Therefore, this present disclosure intends to construct a physical information KAN (PIKAN, that is, replacing the MLP-based neural network in PINN with KAN) for seepage simulation in heterogeneous porous media for the first time, and to explore the computational performance of PIKAN and the advantages of the mixed pressure-velocity formula compared with the pure pressure formula, so as to promote PIKAN to get more and more attention and application in the field of porous media seepage numerical simulation.

### SUMMARY

The purpose of this present disclosure is to provide a PIKAN-based heterogeneous reservoir seepage simulation method. The promising KAN is introduced into the flow simulation of porous media for the first time, and a preliminary reference is provided for the development of a general seepage simulation tool based on PIKAN.

In order to achieve the above purpose, the present disclosure provides a heterogeneous reservoir seepage simulation method based on PIKAN, including the following steps:

S1, using three independent KAN networks to approximate a PIKAN of pressure p, velocity component vₓ and velocity component v_{y}, respectively.

S2, constructing a loss function of a mixed pressure-velocity formula including a residual of a mass conservation formula, a residual of Darcy, Äôs law, and a residual of relevant boundary conditions, and optimizing the loss function.

In some embodiments, in S1, three independent KAN networks are used to approximate the PIKAN of pressure p, velocity component vₓ and velocity component v_{y}, respectively, the specific operation is as follows:

for a smooth ƒ: [0,1]ⁿ→°, there is:

$$f ( x ) = f ( {x}_{1} , L , {x}_{n} ) = {\sum }_{q = 1}^{2 n + 1} {Φ}_{q} ( {\sum }_{p = 1}^{n} {ϕ}_{q , p} ( {x}_{p} ) ) \qquad ( 1 )$$

where φ_{q,p}: [0,1]→°; Φ_{q}:°→°; x denotes a vector composed of n independent variables xᵢ, i=1, L, n; ƒ(x) denotes a function of xᵢ for n independent variables; xₚ denotes the p-th component of vector x; a univariate function φ_{q,p} processes the p-th component of vector x and contributes an item to a sum of the q-th external function, there are 2n+1 external functions, and each external function Φ_{q} is a one-variable function
a Chebyshev polynomial function is used to replace the B-spline function;
for a fully connected KAN with L+1 layers, the input layer is marked as the 0-th layer, nₗ denotes a count of neurons in the l-th layer, (l,j) denotes the j-th neurons in layer l, and

$${x}_{j}^{l}$$

denotes an activation value of the neuron, there will be nₗnₗ₊₁ parameterized univariate functions between the l-th layer and the l+1-th layer, where the univariate function connecting (l,j) and (l+1,i) is denoted as

$${T}_{i , j}^{l} ,$$

and the activation value of neuron (l+1,i) is calculated as

$${x}_{j}^{l + 1} = {\sum }_{i = 1}^{{n}_{l}} {T}_{i , j}^{l} ( {x}_{i}^{l} ) \qquad ( 2 )$$

$$where {x}_{j}^{l + 1}$$

denotes a value of the j-th neuron in the l+1-th layer;

$${x}_{i}^{l}$$

denotes a value of the i-th neuron in the l-th layer; nₗ denotes a count of neurons in the l-th layer;
therefore, according to an activation value x^{l} of the l+1-th layer of neurons, a matrix expression of the vector x^{l+1} composed of the activation values of the x^{l+1}-th layer of neurons is as follows:

$${x}^{l + 1 ∘} = {T}^{l} {x}^{l} \qquad ( 3 )$$

where T^{l} denotes a function matrix corresponding to the l-th KAN layer,

$${T}_{i , j}^{l}$$

is in the T^{l}-th row and the j-th column of T^{l}, and

$${T}_{i , j}^{l}$$

is a Chebyshev polynomial function;
all the learning parameters of the Chebyshev polynomial function

$${T}_{i , j}^{l}$$

in KAN are recorded as q, l=0, 1, L, L−1, j=1, 2, L, nₗ, i=1, 2, L, n^{l+1}, it is obtained that when the data of the input layer is x⁰, a neuron value of the output layer of the fully connected KAN with L+1 layers is calculated as follows:

$$KAN ( x , θ ) = ( {T}^{L - 1} ∘ {T}^{L - 2} ∘ L ∘ {T}^{1} ∘ {T}^{0} ) {x}^{0} \qquad ( 4 )$$

where o denotes a composition between functions.

In some embodiments, in S2, a loss function of the mixing pressure-velocity formula is:

$$L ( θ ) = {ω}_{1} {L}_{{PDE}_{1}} + {ω}_{2} {L}_{{PDE}_{2}} + {ω}_{3} {L}_{DB} + {ω}_{4} {L}_{NB} \qquad ( 5 )$$

where L(q) denotes a loss function; ω₁, ω₂, ω₃, ω₄ are all weighted coefficients; L_{PDE1} denotes a residual of a mass conservation formula; L_{PDE2} denotes a residual of Darcy's law; L_{DB} denotes a residual of a Dirichlet boundary condition; L_{NB} denotes a residual of a Neumann boundary condition.

In some embodiments, the expression of the residual L_{PDE1} of the mass conservation formula is as follows:

$${L}_{{PDE}_{1}} = \frac{1}{{N}_{in}} {\sum }_{i = 1}^{{N}_{in}} {( \frac{\partial {v}_{x}}{\partial x} + \frac{\partial {v}_{y}}{\partial y} )}^{2} {\vert}_{( {x}_{i} , {y}_{i} )} \qquad ( 6 )$$

where Nᵢₙ denotes a count of collocation points within a computational domain; (xᵢ,yᵢ) denotes a coordinate of a collocation point; x, y are spatial independent variables of the function; vₓ and v_{y} denote components of velocity v in directions of x and y respectively.

In some embodiments, the expression of the residual L_{PDE2} of Darcy's law is as follows:

$${L}_{{PDE}_{2}} = \frac{1}{{N}_{in}} {\sum }_{i = 1}^{{N}_{in}} {( {v}_{x} - k \frac{\partial p}{\partial x} )}^{2} {\vert}_{( {x}_{i} , {y}_{i} )} + \frac{1}{{N}_{in}} {\sum }_{i = 1}^{{N}_{in}} {( {v}_{y} - k \frac{\partial p}{\partial x} )}^{2} {\vert}_{( {x}_{i} , {y}_{i} )} \qquad ( 7 )$$

where k denotes permeability.

In some embodiments, the expression of the residual of the Dirichlet boundary condition is as follows:

$${L}_{DB} = \frac{1}{{N}_{DB}} {\sum }_{i = 1}^{{N}_{DB}} {( p - g )}^{2} {\vert}_{( {x}_{i} , {y}_{i} )} \qquad ( 8 )$$

where N_{DB} denotes a count of points on the Dirichlet boundary; p denotes a predicted value of PIKAN at collocation point (xᵢ,yᵢ); g denotes a Dirichlet boundary condition value.

In some embodiments, the expression of the residual of the Neumann boundary condition is as follows:

$${L}_{NB} = \frac{1}{{N}_{NB}} {\sum }_{i = 1}^{{N}_{NB}} {( {v}_{x} - {h}_{x} )}^{2} {\vert}_{( {x}_{i} , {y}_{i} )} + \frac{1}{{N}_{NB}} {\sum }_{i = 1}^{{N}_{NB}} {( {v}_{y} - {h}_{y} )}^{2} {\vert}_{( {x}_{i} , {y}_{i} )} \qquad ( 9 )$$

where N_{NB} denotes a count of points on the Neumann boundary; hₓ denotes a x-direction velocity value given by the Neumann boundary condition; h_{y} denotes a y-direction velocity value given by the Neumann boundary condition

Therefore, the present disclosure uses the above-mentioned PIKAN-based heterogeneous reservoir seepage simulation method, introduces the promising KAN into the porous media flow simulation for the first time, and provides a preliminary reference for the development of a general seepage simulation tool based on PIKAN.

### BRIEF DESCRIPTION OF THE DRAWINGS

FIG. 1A and FIG. 1B, show a comparison between the MLP based on PINN (FIG. 1A) and the KAN based on PIKAN (FIG. 1B);

FIG. 2 is a structural diagram of P-V-3-PIKAN;

FIG. 3A and FIG. 3B are reservoir domains in Example 1; where FIG. 3A is a computational domain; FIG. 3B is a collocation point;

FIG. 4A-D are a loss function and its sub-terms of different methods in Example 1, where FIG. 4A is a total loss; FIG. 4B is a PDE loss; FIG. 4C is a Dirichlet boundary condition loss; FIG. 4D is a Neumann boundary condition loss;

FIG. 5A-D are a pressure distribution predicted by different methods in Example 1, where FIG. 5A is an exact solution; FIG. 5B is a P-PIKAN; FIG. 5C is a P-V-3-PINN; FIG. 5D is a P-V-3-PIKAN;

FIG. 6A-C are a vₓ distribution predicted by different methods in Example 1, where FIG. 6A is an exact solution; FIG. 6B is a P-V-3-PINN; FIG. 6C is a P-V-3-PIKAN;

FIG. 7A-C are a v_{y} distribution predicted by different methods in Example 1; where FIG. 7A is the exact solution; FIG. 7B is a P-V-3-PINN; FIG. 7C is a P-V-3-PIKAN;

FIG. 8 is a reservoir domain in Example 2;

FIG. 9A-D are a loss function and its sub-terms of different methods in Example 2, where FIG. 9A is a total loss; FIG. 9B is a PDE loss; FIG. 9C is a Dirichlet boundary condition loss; FIG. 9D is a Neumann boundary condition loss;

FIG. 10A-D show the pressure distribution predicted by different methods in Example 2; where FIG. 10A is the analytical solution; FIG. 10B is a P-PIKAN; FIG. 10C is a P-V-3-PINN; and FIG. 10D is a P-V-3-PIKAN;

FIG. 11A-C show a vₓ distribution predicted by different methods in Example 2, where FIG. 11A is an exact solution; FIG. 11B is a P-V-3-PINN; FIG. 11C is a P-V-3-PIKAN;

FIG. 12A-C are a v_{y} distribution predicted by different methods in Example 2, where FIG. 12A is an exact solution; FIG. 12B is a P-V-3-PINN; FIG. 12C is a P-V-3-PIKAN:

FIG. 13A and FIG. 3B show a reservoir domain and collocation points generated by the Latin hypercube sampling strategy in Example 3; where FIG. 13A is a reservoir domain; FIG. 13B is a collocation point for training;

FIG. 14A-D show a loss function and its sub-terms of different methods in Example 3; where FIG. 14A is the total loss; FIG. 14B is a PDE loss; FIG. 14C is a Dirichlet boundary condition loss; FIG. 14D is a Neumann boundary condition loss;

FIG. 15A-D show the pressure distribution predicted by different methods in Example 3; where FIG. 15A is an exact solution; FIG. 15B is P-PIKAN; FIG. 15C is P-V-3-PINN; and FIG. 15D is P-V-3-PIKAN;

FIG. 16A-D show a vₓ distribution predicted by different methods in Example 3, where FIG. 16A is an exact solution; FIG. 16B is a P-PIKAN; FIG. 16C is a P-V-3-PINN; FIG. 16D is a P-V-3-PIKAN;

FIG. 17A-D are a v_{y} distribution predicted by different methods in Example 3; where FIG. 17A is an exact solution; FIG. 17B is a P-PIKAN; FIG. 17C is a P-V-3-PINN; FIG. 17D is a P-V-3-PIKAN.

### DETAILED DESCRIPTION OF THE EMBODIMENTS

The following is a further explanation of the technical scheme of the present disclosure through drawings and examples.

Unless otherwise defined, the technical terms or scientific terms used in the present disclosure should be understood by people with general skills in the field to which the present disclosure belongs.

The following first introduces the theory used in the present disclosure.

### Control Formula.

The seepage control formula in heterogeneous porous media mainly includes the conservation formula of fluid material and the Darcy's law based on physical experiments. Under the assumption of steady-state flow and no source-sink term, the mass conservation formula of the fluid is as follows:

$$∇ \cdot v = 0 \qquad ( 1 )$$

$$where ∇ = ( \frac{\partial }{\partial x} , \frac{\partial }{\partial y} )$$

denotes the divergence operator; v denotes the seepage velocity of the fluid, there are v=(vₓ,v_{y})^{T} in the two-dimensional case; vₓ and v_{y} denote the components of velocity v in x and y directions, respectively.

Darcy's law is described as:

$$v = - \frac{k ( x , y )}{μ} ∇ p \qquad ( 2 )$$

where k(x,y) denotes the heterogeneous permeability; u denotes the fluid viscosity; p denotes the fluid pressure;
Formula (2) is substituted into Formula (1), and we may get the formula only about pressure P:

$$∇ \cdot ( \frac{k ( x , y )}{μ} ∇ p ) = 0 \qquad ( 4 )$$

In the simulation calculation of the seepage, there are two kinds of formulas. One is the mixed pressure-velocity formula composed of Formula (1) and Formula (2), which takes v and p as the main unknowns at the same time. The other is Formula (3) that only takes p as the main unknown number, which is called the pure pressure formula. The application of the pure pressure formula is the most common in the field of reservoir numerical simulation.

In the absence of internal source and sink terms, as shown in Formula (4), the seepage problem generally has both the Dirichlet boundary condition representing the constant pressure boundary and the Neumann boundary condition representing the closed or constant flow.

$$Dirichlet boundary condition : p ( x , y ) {\vert}_{Γ} \text{?} = g ( x , y ) \qquad ( 4 )$$

$$Neumann boundary condition : \text{?} {\vert}_{Γ} \text{?} = \frac{k ( x , y )}{μ} ∇ p {\vert}_{Γ} \text{?} = h ( x , y )$$

$$\text{?} \text{indicates text missing or illegible when filed}$$

where Γ_{DB} denotes the Dirichlet boundary condition; Γ_{NB} denotes the Neumann boundary; h(x,y)=(hₓ,h_{y}); p(x,y) denotes the pressure function to be solved; g(x,y) denotes the value of the pressure function given by the Dirichlet boundary condition on the boundary Γ_{DB}; h(x,y) denotes the value of the velocity function given by the Neumann boundary on the boundary Γ_{NB}; hₓ and h_{y} denote the components of h(x,y) in the x direction and y direction, respectively.

### Physical Information Neural Network (PINN).

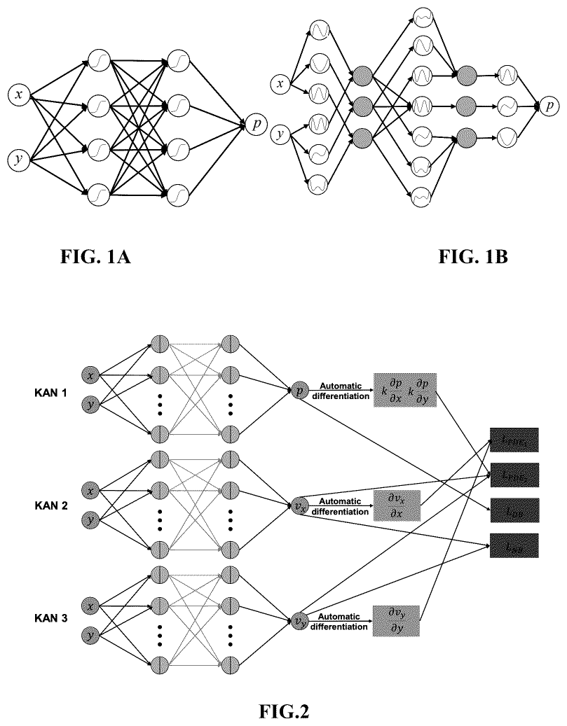

The core idea of PINN is to use a neural network based on an MLP to approximate the solution of partial differential equations. Taking the pure pressure formula in Formula (3) as an example, inspired by the general approximation theorem of MLP, PINN approximates the solution p(x,y) of the definite solution problem composed of boundary conditions in Formula (3) and Formula (4) by constructing a neural network with input space coordinates x and y and output pressure p as shown in FIG. 1.

It is assumed that there is a fully connected MLP of the L+1-th layer in the PINN, that is, there are L−1 hidden layers. The input layer is recorded as the 0th layer, nₗ denotes the count of neurons in the l-th layer, (l,j) denotes the j-th neuron in the l-th layer, xⱼ^{l} denotes the value of the neuron, and x^{l} denotes the vector composed of the values of all neurons in the l-th layer. Then, we may obtain the following

$${x}^{l} = σ ( {W}^{l - 1} {x}^{l - 1} + {b}^{l} ) , 1 \leq l \leq L - 1 \qquad ( 5 )$$

$${x}^{L} = {W}^{L - 1} {x}^{L - 1} + {b}^{L}$$

where the output x^{L} of the last layer is used to approximate the true solution, W^{l-1} and b^{l} denote a weight matrix and a bias vector of the l-th layer, respectively. x^{L} denotes the value of neurons on the L-th layer; W^{L-1} denotes the weight matrix between the L−1-th neurons and the L-th neurons; b^{l} denotes the bias vector of the l layer; x^{L-1} denotes the value of neurons on the L−1-th layer; b^{L} denotes the bias vector of the L-th layer; σ(⋅) denotes a nonlinear activation function. All trainable model parameters, such as weights and biases, are represented as θ.

The above network structure is extended to the general MLP representation form:

$$MLP ( x , θ ) = ( {N}^{L - 1} o σ o {N}^{L - 2} o L o {N}^{1} o σ o {N}^{0} ) {x}^{0} \qquad ( 6 )$$

where o denotes the composition between functions; N^{l}x=W^{l-1}x+b^{l}.

By arranging points on the interior and boundary of the computational domain, it is assumed that the number of collocation points on the interior of the computational domain, the Dirichlet boundary, and the Neumann boundary is Nᵢₙ, N_{DB}, N_{NB} respectively. Then PINN trains the parameters of the neural network by making the collocation points of the neural network in the computational domain satisfy the differential equation as much as possible, and making the collocation points of the neural network on the boundary of the computational domain satisfy the boundary conditions as much as possible. Therefore, during the training process, the loss function L(θ) of the neural network is defined as:

$$L ( θ ) = {ω}_{1} {L}_{PDE} + {ω}_{2} {L}_{DB} + {ω}_{3} {L}_{NB} \qquad ( 7 )$$

$${L}_{PDE} = \frac{1}{{N}_{in}} \text{?} {( \frac{\partial }{\partial x} ( \frac{k ( x , y )}{μ} \frac{\partial p}{\partial x} ) + \frac{\partial }{\partial y} ( \frac{k ( x , y )}{μ} \frac{\partial p}{\partial y} ) )}^{2} \text{?} \qquad ( 8 )$$

$${L}_{DB} = \frac{1}{{N}_{DB}} {\sum }_{i = 1}^{{N}_{DB}} {( p - g )}^{2} \text{?} \qquad ( 9 )$$

$${L}_{NB} = \frac{1}{{N}_{DB}} {\sum }_{i = 1}^{{N}_{DB}} {( - \frac{k}{μ} \frac{\partial p}{\partial x} - {h}_{x} )}^{2} \text{?} + \frac{1}{{N}_{DB}} {\sum }_{i = 1}^{{N}_{DB}} {( - \frac{k}{μ} \frac{\partial p}{\partial y} - {h}_{y} )}^{2} \text{?} \qquad ( 10 )$$

$$\text{?} \text{indicates text missing or illegible when filed}$$

where ω₁, ω₂, ω₃ denote the weighting coefficients of different loss items; L_{PDE} denotes the residual term of the governing formula, and L_{DB} and L_{NB} denote the residual terms of the Dirichlet boundary condition and the Neumann boundary condition, respectively, as shown in Formulas (8), (9) and (10). In general, the mean square error of the L2 norm of the corresponding sample points is used to calculate the three types of losses in Formula (7).

Therefore, PINN converts the fixed-solution problem composed of Formulas (3) and (4) into training the neural network and iteratively updating the neural network parameter θ to minimize the loss function L(θ). Usually, the ADAM (Adaptive Moment Estimation) optimizer, a gradient-based first-order optimization adaptive algorithm, is used to optimize the model parameter θ.

One of the keys to calculating Formula (8) and Formula (10) is to calculate the partial derivative by automatic differentiation (AD). AD tracks the influence of the output of each layer of neurons on the output of the previous layer through the chain rule, and directly calculates the derivative of the network output relative to the input in the calculation diagram. The partial derivative may be calculated using explicit expressions to obtain accurate values, thus avoiding the introduction of truncation errors in traditional numerical approximations. At present, AD is widely used in machine learning and optimization algorithms, which facilitates the development of PINN.

The basic theory of KAN is introduced.

The idea of the KAN network structure comes from the Kolmogorov-Arnold representation theorem, which is proposed by a mathematician named Kolmogorov. The theorem points out that if ƒ is any multivariate continuous function defined on a bounded domain, then the function ƒ may be expressed as a finite number of two-layer nested additions of univariate and continuous functions, that is, any multivariate continuous function may be expressed as a combination of univariate continuous functions and addition operations. That is, for a smooth ƒ: [0,1]ⁿ→°, there is:

$$f ( x ) = f ( {x}_{1} , L , {x}_{n} ) = {\sum }_{q = 1}^{2 n + 1} {Φ}_{q} ( {\sum }_{p = 1}^{n} {∅}_{q , p} ( {x}_{p} ) ) \qquad ( 11 )$$

where φ_{q,p}: [0,1]→°, Φ_{q}: °→° xₚ, are the p-th component of vector x, and the univariate function φ_{q,p} processes the p-th component of vector x and contributes an item to the sum of the q-th external function. There are 2n+1 external functions, and each external function Φ_{q} is a univariate function.

When constructing Kolmogorov networks strictly following the Kolmogorov-Arnold representation theorem, the corresponding properties of φ_{q,p} and Φ_{q} are usually very poor, which makes Kolmogorov networks with shallow structure almost ineffective in practical applications. KAN deepens the shallow Kolmogorov network to construct a univariate function with good properties. In the original KAN, KAN parameterizes each one-dimensional function into a B-spline function, and has a learnable coefficient of the local B-spline basis function. In the present disclosure, the Chebyshev polynomial function is used to replace the B-spline function.

Similarly, assuming that there is a fully connected KAN with L+1 layers, the input layer is marked as the 0-th layer, mi denotes a count of neurons in the l-th layer, (l,j) denotes the j-th neuron in the l-th layer, and

$${x}_{j}^{l}$$

denotes the activation value of the neuron. Between layer l and layer l+1, there will be nₗnₗ₊₁ parameterized univariate functions between the l-th layer and the l+1-th layer, where the univariate function connecting (l,j) and (l+1,i) is denoted as

$${T}_{i , j}^{l} ,$$

and the activation value of neuron (l+1,i) is calculated as follows:

$${x}_{j}^{l + 1} = \text{?} {T}_{i , j}^{l} ( {x}_{i}^{l} ) \qquad ( 12 )$$

$$\text{?} \text{indicates text missing or illegible when filed}$$

Therefore, according to the activation value x^{l} of the l+1 layer of neurons, the matrix expression of the vector x^{l+1} composed of the activation value of the l+1-th layer of neurons is as follows:

$${x}^{l + 1} = {T}^{l} {x}^{l} \qquad ( 13 )$$

where T^{l} is the function matrix corresponding to the l-th KAN layer, and

$${T}_{i , j}^{l}$$

is in the i-th row and j-th column of T^{l}. In this present disclosure,

$${T}_{i , j}^{l}$$

is a Chebyshev polynomial function.

All the learnable parameters of all Chebyshev polynomial functions

$${T}_{i , j}^{l}$$

(l=0, 1, L, L−1, j=1, 2, L, nₗ, i=1, 2, L, nₗ₊₁) in KAN are still recorded as q, then it may be obtained that when the input layer data is x⁰, the neuron value of the output layer of the fully connected KAN with L+1 layers is calculated as:

$$KAN ( x , \text{?} ) = ( {T}^{L - 1} o {T}^{L - 2} oL o {T}^{1} o {T}^{0} ) {x}^{0} \qquad ( 14 )$$

$$\text{?} \text{indicates text missing or illegible when filed}$$

The Chebyshev polynomial function has the same good continuity as the B-spline function, so it may be similar to PINN. The derivative of the pressure or velocity of the output layer to the spatial coordinates of the input layer may be obtained by automatic differentiation, and the KAN may also be trained by error back propagation.

PIKAN constructed in the present disclosure.

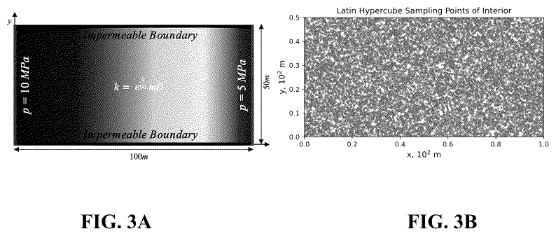

As shown in FIG. 2, PIKAN essentially replaces the MLP based on PINN with KAN. Therefore, the essence of PIKAN and PINN is different, and the only difference is that the basic architecture of the neural network is different, but the loss function and optimization algorithm are the same. In 2023, Lehmann et al. discussed that using the mixed pressure-velocity formula in PINN may achieve higher calculation accuracy and better convergence for seepage simulation in heterogeneous porous media than the pure pressure formula, and found that using three independent neural networks to approximate the pressure (p) and two velocity components (vₓ, v_{y}) PINN (P-V-3-PINN, as shown in FIG. 3) may achieve better calculation performance than using only one neural network to approximate the pressure (p) and two velocity components (vₓ, v_{y}). Therefore, the present disclosure will focus on testing whether the conclusions in the PIKAN framework are similar to those in the PINN framework in subsequent implementations, and compare the calculation performance of PIKAN and PINN.

Taking P-V-3-PIKAN with mixed pressure-velocity formula in FIG. 2 as an example, as shown in Formulas (15-18) and Formula (9), the loss function with mixed pressure-velocity formula is composed of the residual of mass conservation formula L_{PDE1}, the residual of Darcy's law L_{PDE2} and the residual of related boundary conditions L_{DB} and L_{NB}. In this present disclosure, the PIKAN model in the present disclosure is implemented through the Pytorch-based ChebyKAN solution framework, and the neural network is trained using the two-Strategy commonly used in PINN: First, the Adam algorithm and the specified number of iterations are used to minimize the loss function; then, the L-BFGS algorithm is used to achieve the final convergence of the loss function.

$$L ( θ ) = {ω}_{1} {L}_{{PDE}_{1}} + {ω}_{2} {L}_{{PDE}_{2}} + {ω}_{3} {L}_{DB} + {ω}_{3} {L}_{NB} \qquad ( 15 )$$

$${L}_{{PDE}_{1}} = \frac{1}{{N}_{in}} \text{?} {( \frac{\partial {v}_{x}}{\partial x} + \frac{\partial {v}_{y}}{\partial y} )}^{2} \text{?} \qquad ( 6 )$$

$${L}_{{PDE}_{2}} = \frac{1}{{N}_{in}} \text{?} {( {v}_{x} - k \frac{\partial p}{\partial x} )}^{2} \text{?} + \frac{1}{{N}_{in}} \text{?} {( {v}_{y} - k \frac{\partial p}{\partial x} )}^{2} \text{?} \qquad ( 7 )$$

$${L}_{DB} = \frac{1}{{N}_{DB}} {\sum }_{i = 1}^{{N}_{DB}} {( p - g )}^{2} \text{?} \qquad ( 8 )$$

$${L}_{NB} = \frac{1}{{N}_{DB}} {\sum }_{i = 1}^{{N}_{DB}} {( {v}_{x} - {h}_{x} )}^{2} \text{?} + \frac{1}{{N}_{DB}} {\sum }_{i = 1}^{{N}_{DB}} {( {v}_{y} - {h}_{y} )}^{2} \text{?} \qquad ( 9 )$$

$$\text{?} \text{indicates text missing or illegible when filed}$$

The computational performances of the three methods are compared through specific examples. The first method is to use a mixed pressure-velocity formula and three neural networks to approximate the PINNs of pressure, vₓ and v_{y}, respectively, abbreviated as P-V-3-PINN. The second method is PIKAN using a pure pressure formula, abbreviated as P-PIKAN. The third method is P-V-3-PIKAN shown in FIG. 2. The following is intended to test whether the mixed pressure velocity formula in the PIKAN framework has the advantage of dealing with the heterogeneous domain compared with the pure pressure formula by comparing the calculation performance of P-V-3-PIKAN and PIKAN, and by comparing the calculation performance of P-V-3-PIKAN and P-V-3-PINN to test whether KAN has certain advantages over MLP in the problem studied by the present disclosure.

### Example 1

This example is a single-phase flow in a two-dimensional heterogeneous domain, as shown in FIG. 3 (a). The rectangular region is 100 meters in length and 50 meters in width. The left and right sides are fixed at 10 MPa and 5 MPa, respectively, and the upper and lower sides are closed. The analytical expression of the heterogeneous permeability is k(x,y)=e^{x/50}. It may be known that the exact solution of the pressure distribution in this example is as follows:

$$p ( x , y ) = \frac{5}{1 - {e}^{- 2}} {e}^{- \frac{x}{50}} + \frac{10 {e}^{- 2} - 5}{{e}^{- 2} - 1} , {v}_{x} ( x , y ) = \frac{1}{10 {e}^{- 2} - 10} , {v}_{y} ( x , y ) = 0 \qquad ( 19 )$$

where vₓ(x,y) is the velocity function in the direction of x in this example; v_{y}(x,y) is the velocity function in the direction of y in this example.

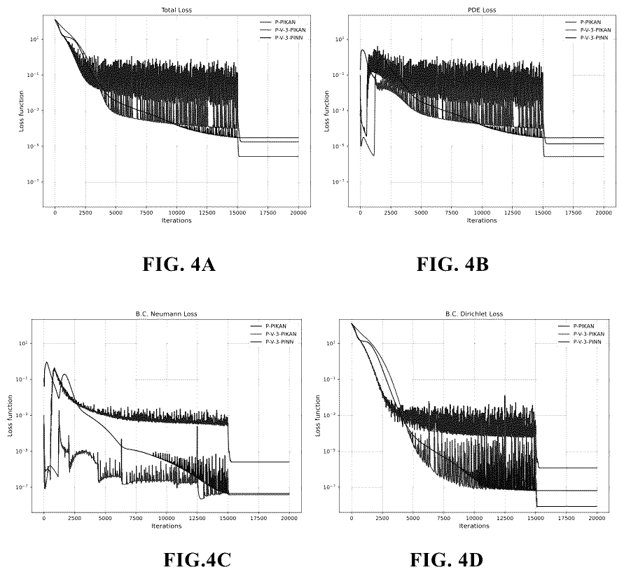

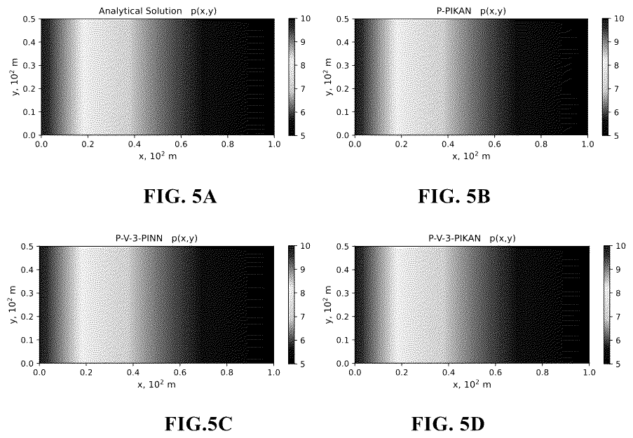

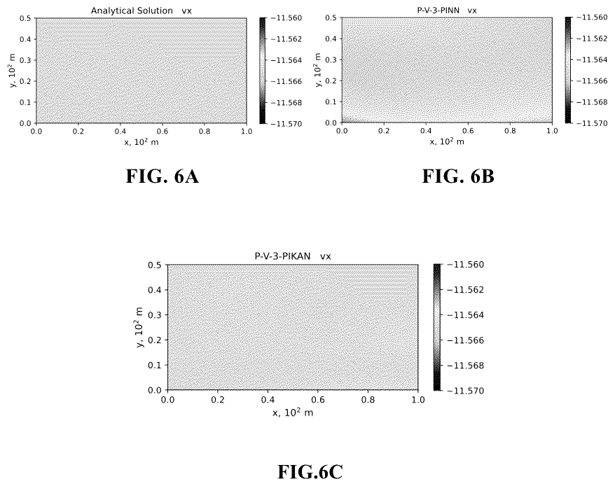

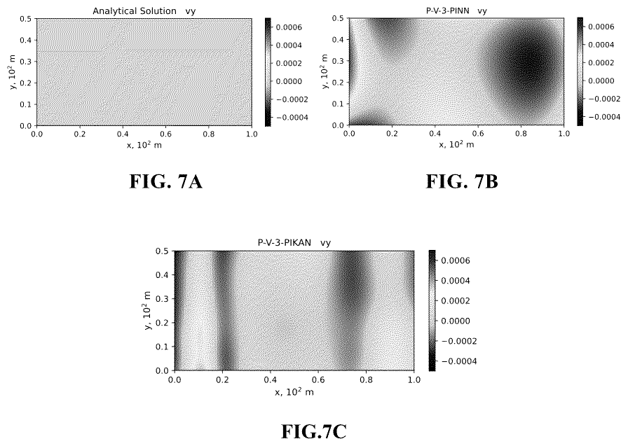

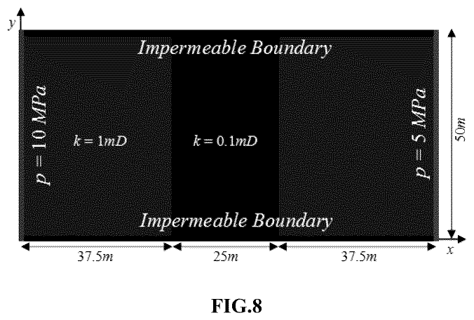

Table 1 lists the relevant parameters in the P-V-3-PINN, P-PINN, and P-V-3-PIKAN constructed in this example. As shown in FIG. 3 (b), 214 and 210 collocation points are randomly generated inside and on the boundary of the computational domain by using the Latin hypercube sampling strategy. The weight of each loss item in Formula (7) or Formula (15) is set to 1. For the training process, the loss function is first minimized by the Adam optimizer in 15000 iterations, and then further optimized by the L-BFGS optimizer in 5000 iterations. FIG. 4 compares the total loss function and its sub-terms (including PDE loss, Neumann boundary condition loss, and Dirichlet boundary condition loss) of the three methods in the training process with the optimization steps. The Cartesian collocation points are selected on the computational domain (the spacing in the x direction is 1 m, and the spacing in the y direction is 1 m, a total of 101×51=5151 points). FIGS. 5, 6, and 7 show the pressure on the Cartesian collocation points predicted by different methods, the distribution of vₓ and v_{y}, and the exact solution in Formula (19). Table 2 quantitatively calculates the pressure predicted by the three methods in FIG. 5, FIG. 6, and FIG. 7, and the L2 error of the vₓ and v_{y} distributions. It may be seen from these pictures and tables that: In this example, the value of P-V-3-PIKAN in each item of the loss function is the lowest of the three methods. Where the P-V-3-PIKAN and P-V-3-PINN using the mixed pressure-velocity formula may make each item of the loss function decrease significantly faster than the P-PINN using the pure pressure formula, especially the loss of the Neumann boundary condition, indicating that the mixed formula may significantly improve the calculation performance of PIKAN compared with the pure pressure formula. Moreover, the vₓ and v_{y} distributions calculated by P-V-3-PIKAN are closer to the exact solution than the vₓ and v_{y} distributions calculated by P-V-3-PINN using the same hybrid formula, especially the vₓ distribution, which reveals that the PIKAN framework based on KAN has advantages over the PINN framework based on MLP in this Example. The L₂ error value calculated in Table 2 further quantitatively demonstrates the conclusions of the above analysis, indicating that the calculation performance of P-V-3-PIKAN in this example is the best of the three methods. Compared with P-V-3-PIKAN and P-PIKAN, the L₂ error of the mixed formula is only 1/10 of the L₂ error of the pure pressure formula, indicating that the mixed formula may be significantly better than the pure pressure formula. Compared with P-V-3-PIKAN and P-V-3-PINN. In the case of using the mixed formula, the L₂ error of the PIKAN framework based on KAN is only 0.4279 of the PINN framework based on MLP, indicating that KAN is superior to MLP in this example.

TABLE 1
Parameters of neural network and optimizer of
the three methods in Example 1 and Example 2

| | | | Number of | | | | | |
|---|---|---|---|---|---|---|---|---|
| | Number of | | neurons in | | | | Number of | |
| | hidden | Sum of | the hidden | Degree of | Optimizer | | points | |
| Method | layers | parameters | layer | polynomial | Adams | LBFGS | PDE | BC |
| P-PIKAN | 3 | 9306 | 22 | 8 | 15000 | 5000 | 2¹⁴ | 2¹⁰ |
| P-V-3- | 4 | 9303 | 31 for (p) | — | The | The | | |
| PINN | | | 31 for (vₓ) | | number of | number of | | |
| | | | 31 for (v_{y}) | | iterations. | iterations. | | |
| P-V-3- | 4 | 8910 | 10 for (p) | 8 | Learning | Learning | | |
| PIKAN | | | 10 for (vₓ) | | rate 10⁻⁴ | rate 10⁻¹ | | |
| | | | 10 for (v_{y}) | | | | | |

TABLE 2
L₂ error of pressure and velocity distribution
predicted by different methods in Example 1

| method | p(x, y) | vₓ | v_{y} |
|---|---|---|---|
| P-V-3-PIKAN | 2.618983e⁻⁰⁵ | 0.000191 | 0.000125 |
| P-V-3-PINN | 0.000110 | 0.000624 | 0.000169 |
| P-PIKAN | 0.000202 | — | — |

### Example 2

As shown in FIG. 8, the only difference between this example and Example 1 is that the heterogeneous permeability in this example no longer has an analytical continuous function form, but is partitioned. Among them, in the middle of the blue area, the permeability is 0.1 mD, and the permeability of the red area is 1 mD. The analytical solution of this problem is as follows:

$$p ( x , y ) = \{ \begin{matrix}10 - x / 65 x < 37.5 \\ 10 - 37.5 / 65 - 10 ( x - 37.5 ) / 65 37.5 \leq x \leq 62.5 \\ 10 - 37.5 / 65 - 250 / 65 - ( x - 62.5 ) / 65 x > 62.5\end{matrix} \qquad ( 20 )$$

$${v}_{x} = \frac{1}{65} , {v}_{y} = 0$$

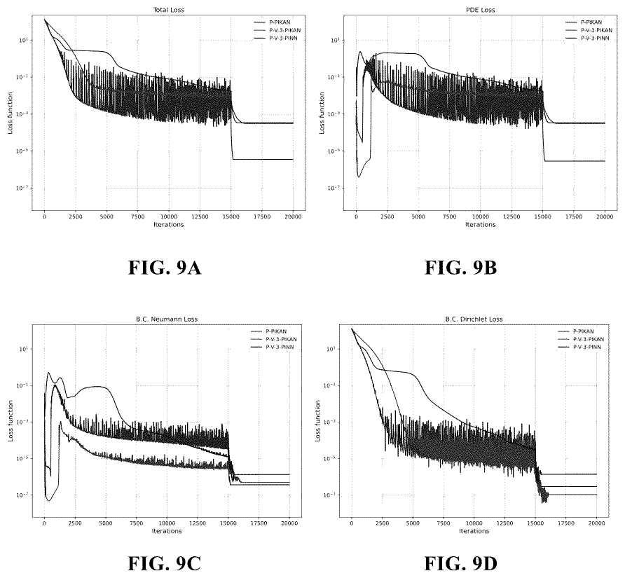

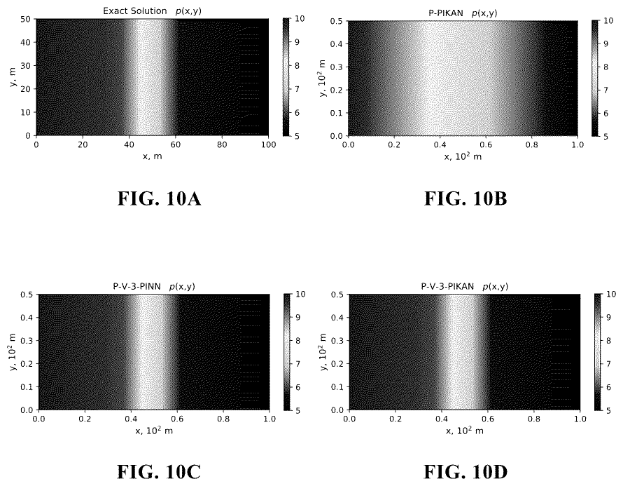

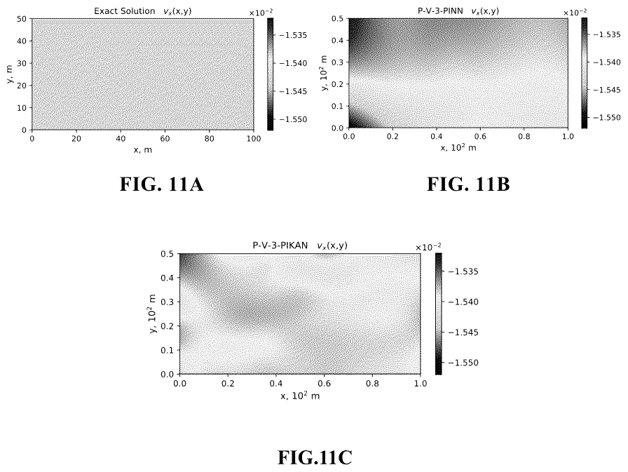

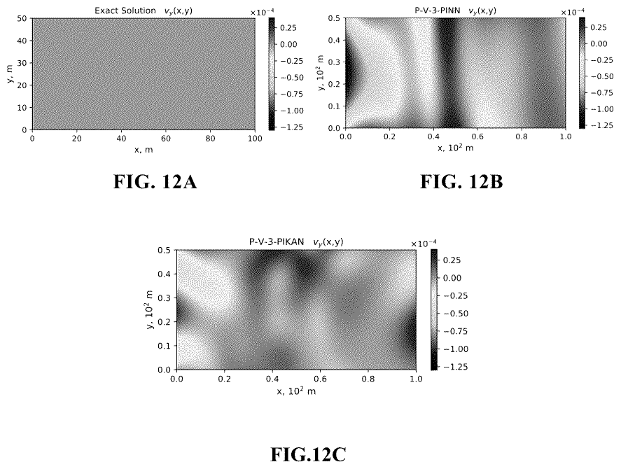

The settings of the three methods of this Example in the structure of the neural network, the generation of the collocation points, and the parameters of the optimizer are the same as those of Example 1. FIG. 9 compares the total loss function and its sub-terms (including PDE loss, Neumann boundary condition loss, and Dirichlet boundary condition loss) of the three methods in the training process with the optimization steps. In order to test the accuracy of the three methods, the same Cartesian collocation points as Example 1 are selected on the computational domain. FIGS. 10, 11, and 12 show the pressure, vx, and vy distributions obtained by different methods and the exact solutions in Formula (20). Table 3 quantitatively calculates the L₂ errors of various distributions predicted by the three methods in FIG. 10, FIG. 11, and FIG. 12. It may be seen from these pictures and tables:

Firstly, in this example, P-V-3-PIKAN decreases faster than P-V-3-PINN in various loss terms, and the distributions of vₓ and v_{y} predicted by P-V-3-PIKAN are closer to the reference solution visually than the distributions of vₓ and v_{y} predicted by P-V-3-PINN. The L₂ error shown in Table 3 also quantitatively demonstrates that the error of P-V-3-PINN is more than twice that of P-V-3-PIKAN in the calculation of velocity distribution. All these indicate that the KAN-based PIKAN framework is superior to the MLP-based PINN framework in this example.

Secondly, although FIG. 9(a) shows that P-PIKAN with the pure pressure formula may achieve the optimal convergence speed and the lowest loss function value among the three methods, it does not mean that P-PIKAN has the highest calculation accuracy. On the contrary, the difference between the predicted pressure distribution and the exact solution of P-PIKAN in FIG. 10 (b) is very obvious, and the calculation error is very significant, reaching 1000 times the P-V-3-PIKAN error or P-V-3-PINN error using the mixed formula. This is because when the pure pressure formula is used, for the permeability of the discontinuous distribution in this example, when it is determined that a sample point is located in a certain area, the permeability in the area near the point will be a constant, so that the k(x,y) in the Formula (3) at this point will be treated as a constant without demand derivative, so that the formula at all sample points in the whole computational domain is essentially the same, so that the P-PIKAN in this example actually depicts the seepage problem in the homogeneous computational domain, and does not really consider the heterogeneous permeability distribution in this example. The pressure distribution predicted by (b) P-PIKAN in FIG. 10 shows an obvious slope-invariant linear distribution in the x direction of the whole calculation domain, which also verifies that P-PIKAN actually solves the definite solution problem of the reservoir domain with homogeneous permeability distribution combined with the boundary conditions of this example. The results illustrate the significance of using the mixed pressure-velocity formula instead of the pure pressure formula to deal with this sub-regional heterogeneous reservoir model.

TABLE 3
L₂ error of pressure and velocity distribution
predicted by different methods in Example 2

| Method | P (MPa) | vₓ (cm/s) | v_{y} (cm/s) |
|---|---|---|---|
| P-V-3-PIKAN | 1.1988 × 10⁻³ | 8.7127 × 10⁻⁴ | 6.2250 × 10⁻⁴ |
| P-V-3-PINN | 8.5280 × 10⁻⁴ | 2.3164 × 10⁻³ | 1.4999 × 10⁻³ |
| P-PIKAN | 7.4551 × 10⁻¹ | — | — |

### Example 3

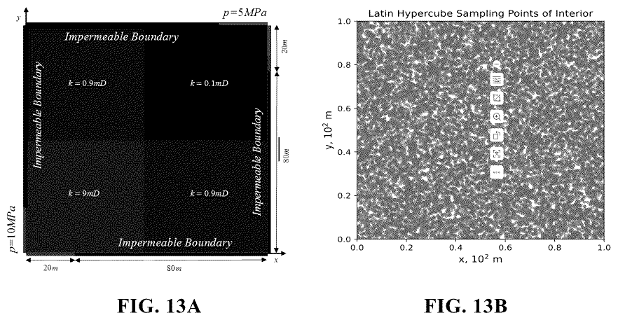

This example is a two-dimensional flow problem on a heterogeneous domain. As shown in FIG. 13, the calculation domain may be divided into four regions, where the permeability in the red region is 9 mD, the permeability in the bright blue region is 0.9 mD, and the permeability in the light blue region is 0.1 mD. The pressure is 10 MPa and 5 MPa at the lower left corner and the upper right corner, respectively, and the other boundaries are closed. Table 4 lists the relevant parameters in the P-V-3-PINN, P-PINN, and P-V-3-PIKAN constructed in this Example. It may be seen that for this more complex problem, this example increases the number of neurons in each hidden layer, thus appropriately increasing the total number of parameters of each neural network.

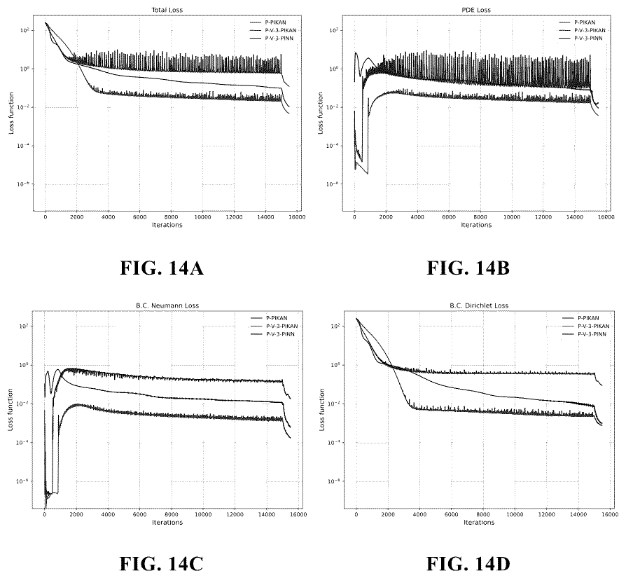

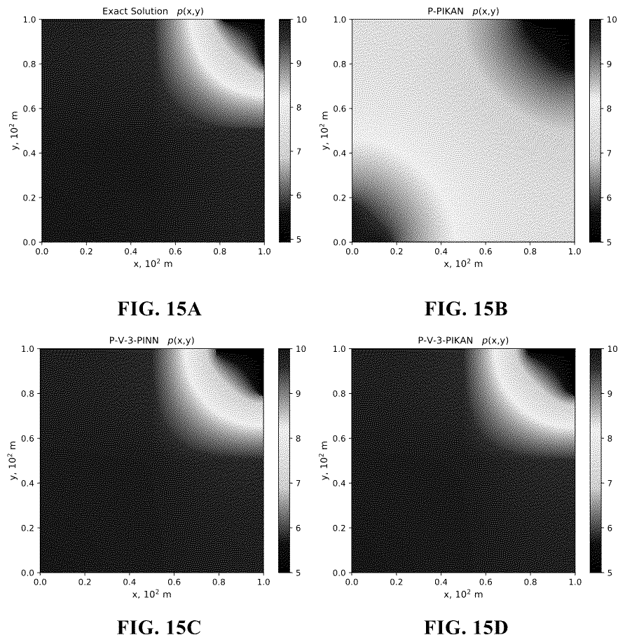

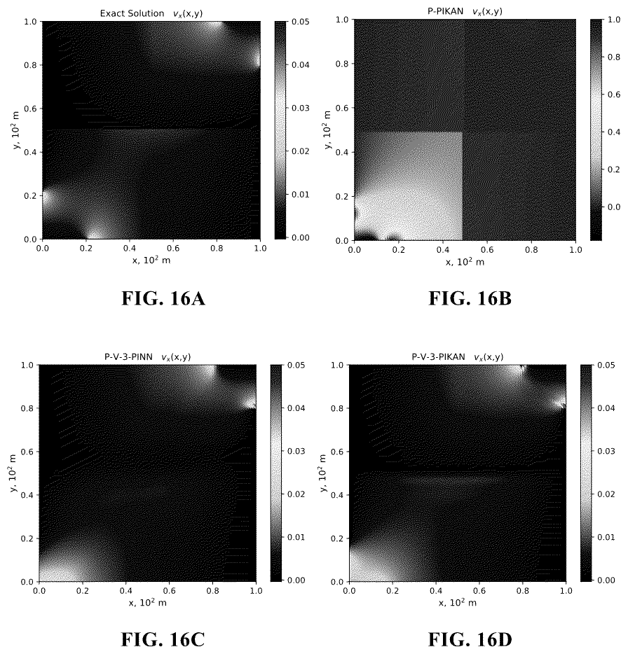

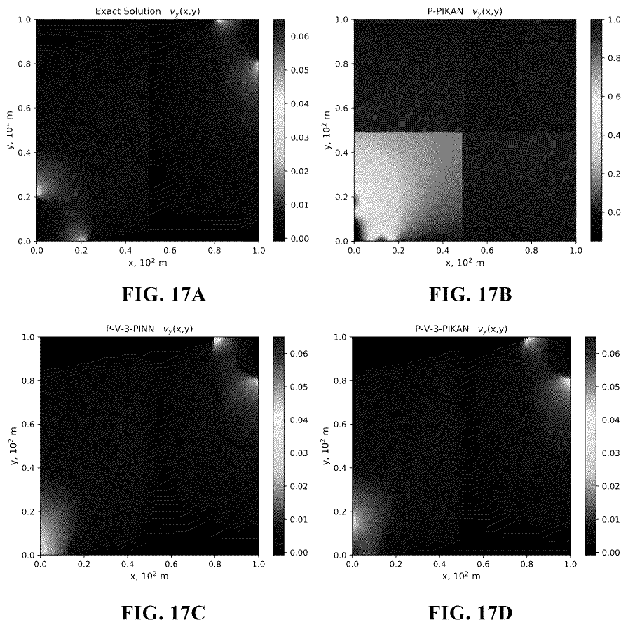

FIG. 14 compares the total loss function and its sub-terms (including PDE loss, Neumann boundary condition loss, and Dirichlet boundary condition loss) of the three methods in the training process with the optimization steps. Cartesian collocation points are arranged on the computational domain to test the accuracy of these three methods, and the corresponding reference solutions are obtained by COMSOL Multiphysics. FIGS. 15, 16, and 17 show the pressure, vₓ and v_{y} distributions and exact solutions obtained by different methods, respectively. Table 5 quantitatively calculates the L₂ errors of various distributions predicted by the three methods in FIG. 15, FIG. 16 and FIG. 17. It may still be seen from these pictures and tables that in the two-dimensional flow problem of this example, P-V-3-PIKAN obviously decreases faster than P-V-3-PINN in various loss terms, and the distributions of vₓ and v_{y} predicted by P-V-3-PIKAN are closer to the reference solution visually than the distributions of vₓ and v_{y} predicted by P-V-3-PINN. The L₂ errors shown in Table 5 also quantitatively demonstrate that the error of P-V-3-PINN is higher than that of P-V-3-PIKAN in the calculation of velocity distribution. All these indicate that the KAN-based PIKAN framework is superior to the MLP-based PINN framework in this example. In addition, the difference between the pressure distribution predicted by P-PIKAN and the exact solution in FIG. 15(b) is very obvious, which is 100 times the error of P-V-3-PIKAN using the mixed formula and 50 times the error of P-V-3-PINN. This is because, as previously analyzed, the P-PIKAN using the pure pressure formula actually solves the fixed solution problem of the reservoir domain with homogeneous permeability distribution combined with the boundary conditions of this example, once again supporting the necessity of using the mixed pressure-velocity formula to replace the pure pressure formula when dealing with this sub-regional heterogeneous reservoir model.

TABLE 4
Parameters of the neural network and optimizer of the three methods in Example 3

| | | | Number of | | | | | |
|---|---|---|---|---|---|---|---|---|
| | Number of | | neurons in | | | | Number of | |
| | hidden | Sum of | the hidden | Degree of | Optimizer | | points | |
| Model | layers | parameters | layer | polynomial | Adams | LBFGS | PDE | BC |
| P-PIKAN | 4 | 15243 | 23 for (p) | 8 | 15000 | 500 | 2¹⁴ | 2¹⁰ |
| P-V-3- | 4 | 14742 | 40 for (p) | — | The | The | | |
| PINN | | | 40 for (vₓ) | | number of | number of | | |
| | | | 40 for (v_{y}) | | iterations. | iterations. | | |
| P-V-3- | 4 | 14904 | 13 for (p) | 8 | Learning | Learning | | |
| PIKAN | | | 13 for (vₓ) | | rate 10⁻⁴ | rate 10⁻¹ | | |
| | | | 13 for (v_{y}) | | | | | |

TABLE 5
L₂ error of pressure and velocity distribution
predicted by different methods in Example 3

| Method | P (MPa) | vₓ (cm/s) | v_{y} (cm/s) |
|---|---|---|---|
| P-V-3-PIKAN | 1.7123 × 10⁻² | 2.6216 × 10⁻³ | 2.3088 × 10⁻³ |
| P-V-3-PINN | 4.7411 × 10⁻² | 2.8385 × 10⁻³ | 2.9015 × 10⁻³ |
| P-PIKAN | 2.0459 | 1.2763 × 10⁻¹ | 1.2813 × 10⁻¹ |

Natural resource extraction methods based on the disclosed PIKAN methods allow for extraction of water, oil or gas resources from heterogeneous reservoirs. By constructing a PIKAN reservoir seepage model, well locations, sizes, depths and related parameters may be optimized to limit losses and increase yields from heterogenous reservoirs. PIKAN models may be employed by skilled artisan to optimize any of a number of variables according to art-recognized principles. By implementing water, oil or gas extraction based on predicted seepage patterns predicted with PIKAN methods, higher production and lower losses can be realized in comparison with existing methods of modeling seepage patterns.

It is worth noting that the contents not elaborated in this present disclosure are all existing technologies, which are well known to technicians in this field.

Therefore, this present disclosure adopts the above-mentioned PIKAN-based heterogeneous reservoir seepage simulation method, introduces the promising KAN into the flow simulation of porous media for the first time, and provides a preliminary reference for the development of general seepage simulation tools based on PIKAN.

Finally, it should be explained that the above embodiments are only used to explain the technical scheme of the present disclosure rather than restrict it. Although the present disclosure is described in detail concerning the better embodiment, the ordinary technical personnel in this field should understand that they may still modify or replace the technical scheme of the present disclosure, and these modifications or equivalent substitutions cannot make the modified technical scheme out of the spirit and scope of the technical scheme of the present disclosure.

What is claimed is:

1. A heterogeneous reservoir seepage simulation method based on PIKAN, comprising the following steps:
S1, using three independent KAN networks to approximate a PIKAN of pressure p, velocity component vₓ and velocity component v_{y}, respectively;
S2, constructing a loss function of a mixed pressure-velocity formula comprising a residual of a mass conservation formula, a residual of Darcy's law, and a residual of relevant boundary conditions, and optimizing the loss function.

2. The heterogeneous reservoir seepage simulation method based on PIKAN according to claim 1, wherein in S1, three independent KAN networks are used to approximate the PIKAN of p, velocity component vₓ and velocity component v_{y}, respectively, the specific operation is as follows:
for a smooth ƒ: [0,1]ⁿ→°, there is:
$$f ( x ) = f ( {x}_{1} , L , {x}_{n} ) = {\sum }_{q = 1}^{2 n + 1} {Φ}_{q} ( {\sum }_{p = 1}^{n} {∅}_{q , p} ( {x}_{p} ) ) \qquad ( 1 )$$
where φ_{q,p}: [0,1]→°; Φ_{q}:°→°; x denotes a vector composed of n independent variables xᵢ, i=1, L, n; ƒ(x) denotes a function of xᵢ for n independent variables; xₚ denotes the p-th component of vector x; a univariate function φ_{q,p} processes the p-th component of vector x and contributes an item to a sum of the q-th external function, there are 2n+1 external functions, and each external function Φ_{q} is a one-variable function;
wherein a Chebyshev polynomial function is used to replace the B-spline function;
wherein, for a fully connected KAN with L+1 layers, the input layer is marked as the 0-th layer, nₗ denotes a count of neurons in the l-th layer, (l,j) denotes the l-th neurons in layer l, and
$${x}_{j}^{l}$$
denotes an activation value of the neuron, there will be nₗnₗ₊₁ parameterized univariate functions between the l-th layer and the l+1-th layer, where the univariate function connecting (l,j) and (l+1,i) is denoted as
$${T}_{i , j}^{l} ,$$
and the activation value of neuron (l+1,i) is calculated as:
$${x}_{j}^{l + 1} = {\sum }_{i = 1}^{{n}_{l}} {T}_{i , j}^{l} ( {x}_{i}^{l} ) \qquad ( 2 )$$
$$where {x}_{j}^{l + 1}$$
denotes a value of the j-th neuron in the l+1-th layer,
$${x}_{i}^{l}$$
value of the i-th neuron in the l-th layer; nₗ denotes a count of neurons in the l-th layer;
wherein, according to an activation value x^{l} of the l+1-th layer of neurons, a matrix expression of the vector x^{l+1} composed of the activation values of the x^{l+1}-th layer of neurons is as follows:
$${x}^{l + 1 ∘} = {T}^{l} {x}^{l} \qquad ( 3 )$$
where T^{l} denotes a function matrix corresponding to the l-th KAN layer,
$${T}_{i , j}^{l}$$
is in the T^{l}-th row and the j-th column of T^{l}, and
$${T}_{i , j}^{l}$$
is a Chebyshev polynomial function;
wherein all the learning parameters of the Chebyshev polynomial function
$${T}_{i , j}^{l}$$
in KAN are recorded as θ, l=0, 1, L, L−1, j=1, 2, L, nₗ, i=1, 2, L, n^{l+1}, it is obtained that when the data of the input layer is x⁰, a neuron value of the output layer of the fully connected KAN with L+1 layers is calculated as follows:
$$K A N ( x , θ ) = ( {T}^{L - 1} ∘ {T}^{L - 2} ∘ L ∘ {T}^{1} ∘ {T}^{0} ) {x}^{0} \qquad ( 4 )$$
where o denotes a composition between functions.

3. The heterogeneous reservoir seepage simulation method based on PIKAN according to claim 2, wherein in S2, a loss function of the mixing pressure-velocity formula is:
$$L ( θ ) = {ω}_{1} {L}_{{PDE}_{1}} + {ω}_{2} {L}_{{PDE}_{2}} + {ω}_{3} {L}_{DB} + {ω}_{4} {L}_{NB} \qquad ( 5 )$$
where L(θ) denotes a loss function; ω₁, ω₂, ω₃, ω₄ are all weighted coefficients; L_{PDE1} denotes a residual of a mass conservation formula; L_{PDE2} denotes a residual of Darcy's law; L_{DB} denotes a residual of a Dirichlet boundary condition; L_{NB} denotes a residual of a Neumann boundary condition.

4. The heterogeneous reservoir seepage simulation method based on PIKAN according to claim 3, wherein the expression of the residual L_{PDE1} of the mass conservation formula is as follows:
$${L}_{{PDE}_{1}} = \frac{1}{{N}_{in}} {\sum }_{i = 1}^{{N}_{in}} {( \frac{\partial {v}_{x}}{\partial x} + \frac{\partial {v}_{y}}{\partial y} )}^{2} {\vert}_{( {x}_{i} , {y}_{i} )} \qquad ( 6 )$$
where Nᵢₙ denotes a count of collocation points within a computational domain; (xᵢ,yᵢ) denotes a coordinate of a collocation point; x, y and are spatial independent variables of the function.

5. The heterogeneous reservoir seepage simulation method based on PIKAN according to claim 3, wherein the expression of the residual L_{PDE2} of Darcy's law is as follows:
$${L}_{{PDE}_{2}} = \frac{1}{{N}_{in}} {\sum }_{i = 1}^{{N}_{in}} {( {v}_{x} - k \frac{\partial p}{\partial x} )}^{2} {\vert}_{( {x}_{i} , {y}_{i} )} + \frac{1}{{N}_{i n}} {\sum }_{i = 1}^{{N}_{in}} {( {v}_{y} - k \frac{\partial p}{\partial x} )}^{2} {\vert}_{( {x}_{i} , {y}_{i} )} \qquad ( 7 )$$
where k denotes permeability.

6. The heterogeneous reservoir seepage simulation method based on PIKAN according to claim 3, wherein the expression of the residual of the Dirichlet boundary condition is as follows:
$${L}_{DB} = \frac{1}{{N}_{DB}} {\sum }_{i = 1}^{{N}_{DB}} {( p - g )}^{2} {\vert}_{( {x}_{i} , {y}_{i} )} \qquad ( 8 )$$
where N_{DB} denotes a count of points on the Dirichlet boundary; p denotes a predicted value of PIKAN at collocation point (xᵢ,yᵢ); g denotes a Dirichlet boundary condition value.

7. The heterogeneous reservoir seepage simulation method based on PIKAN according to claim 3, wherein the expression of the residual of the Neumann boundary condition is as follows:
$${L}_{NB} = \frac{1}{{N}_{NB}} {\sum }_{i = 1}^{{N}_{NB}} {( {v}_{x} - {h}_{x} )}^{2} {\vert}_{( {x}_{i} , {y}_{i} )} + \frac{1}{{N}_{NB}} {\sum }_{i = 1}^{{N}_{NB}} {( {v}_{y} - {h}_{y} )}^{2} {\vert}_{( {x}_{i} , {y}_{i} )} \qquad ( 9 )$$
where N_{NB} denotes a count of points on the Neumann boundary; hₓ denotes a x-direction velocity value given by the Neumann boundary condition; h_{y} denotes a y-direction velocity value given by the Neumann boundary condition.
